(19) United States
(12) Patent Application Publication
(10) Pub. No.: US 2020/0264225 A1
(43) Pub. Date: Aug. 20, 2020

(54) NOISE DETECTION CIRCUIT

(71) Applicant: MITSUBISHI ELECTRIC CORPORATION, Tokyo (JP)

(72) Inventors: Ryota KOBAYASHI, Tokyo (JP); Hideyuki OHASHI, Tokyo (JP); Chiharu MIYAZAKI, Tokyo (JP)

(73) Assignee: MITSUBISHI ELECTRIC CORPORATION, Tokyo (JP)

(21) Appl. No.: 16/756,713

(22) PCT Filed: Dec. 13, 2017
(86) PCT No.: PCT/JP2017/044757

§ 371 Date: Apr. 16, 2020

(51) Int. Cl. G01R 29/26; H03K 5/24

(52) U.S. Cl. CPC G01R 29/26; H03K 5/24

(57) ABSTRACT

A noise detection circuit includes a first reference voltage applying circuit to apply a first reference voltage to a first input terminal of a comparator, a second reference voltage applying circuit to apply a second reference voltage to a second input terminal of the comparator, and a feedback circuit having a first end connected with an output terminal of the comparator and a second end connected with the first input terminal or the second input terminal of the comparator.

### TECHNICAL FIELD

The present invention relates to a noise detection circuit including a comparator.

### BACKGROUND ART

Electromagnetic compatibility (EMC) testing applied to printed circuit boards includes tests for evaluating resistance to transient electromagnetic noise such as electrostatic discharge, lightning surge, and electrical fast transient burst.

In a resistance evaluation test, measuring equipment such as an oscilloscope to which an antenna for EMC measurement is attached is used in some cases for measuring characteristics of transient electromagnetic noise and identifying noise propagation path on a printed circuit board.

The measuring equipment such as an oscilloscope, however, is large in size and hard to carry. There has therefore been a demand for a small noise detection circuit that can easily be carried.

Patent Literature 1 mentioned below teaches a noise detection circuit including two comparators, a peak detector, and a reset circuit.

The two comparators constitute an RS flip flop circuit that holds signals received by the antenna and resets the signals received by the antenna.

### CITATION LIST

### Patent Literatures

Patent Literature 1: JP H08-102716 A

### SUMMARY OF INVENTION

### Technical Problem

A noise detection circuit of the related art includes two comparators. A comparator is an active element, which is typically larger in size than a passive element such as a resistor or a capacitor. Thus, a noise detection circuit of the related art including two comparators has a problem that its circuit size is large.

The present invention has been made to solve such problems as described above, and an object thereof is to provide a noise detection circuit capable of detecting noise by including a single comparator.

### Solution to Problem

A noise detection circuit according to the present invention includes: a comparator including a first input terminal, a second input terminal, and an output terminal, for comparing a potential of the first input terminal with a potential of the second input terminal, and outputting a result of comparison of the potentials through the output terminal; a first reference voltage applying circuit for applying a first reference voltage to the first input terminal; a second reference voltage applying circuit for applying a second reference voltage to the second input terminal; and a feedback circuit having a first end connected with the output terminal and a second end connected with the first input terminal or the second input terminal.

### Advantageous Effects of Invention

According to the present invention, the noise detection circuit includes the first reference voltage applying circuit that applies the first reference voltage to the first input terminal of the comparator, the second reference voltage applying circuit that applies the second reference voltage to the second input terminal of the comparator, and the feedback circuit having the first end connected with the output terminal of the comparator and the second end connected with the first input terminal or the second input terminal of the comparator. Thus, it has an advantageous effect that can detect noise by including a single comparator.

### BRIEF DESCRIPTION OF DRAWINGS

FIG. 1 is a configuration diagram illustrating a noise detection circuit according to a first embodiment.

FIG. 2 is an explanatory diagram illustrating a noise detecting operation of the noise detection circuit illustrated in FIG. 1.

FIG. 3 is an explanatory diagram illustrating the noise detecting operation of a noise detection circuit capable of detecting noise input through a terminal 1b of the differential input terminal 1.

FIG. 4 is a configuration diagram illustrating a noise detection circuit according to a third embodiment.

FIG. 5 is a configuration diagram illustrating another noise detection circuit according to the third embodiment.

FIG. 6 is a configuration diagram illustrating a noise detection circuit according to a fourth embodiment.

FIG. 7 is a configuration diagram illustrating another noise detection circuit according to the fourth embodiment.

FIG. 8 is a configuration diagram illustrating a noise detection circuit according to a fifth embodiment.

FIG. 9 is an explanatory diagram illustrating a noise detecting operation of the noise detection circuit illustrated in FIG. 8.

FIG. 10 is a configuration diagram illustrating another noise detection circuit according to the fifth embodiment.

FIG. 11 is a configuration diagram illustrating a noise detection circuit according to a sixth embodiment.

FIG. 12 is a configuration diagram illustrating another noise detection circuit according to the sixth embodiment.

### DESCRIPTION OF EMBODIMENTS

Embodiments for carrying out the invention will now be described with reference to the accompanying drawings for more detailed explanation of the invention.

First Embodiment.

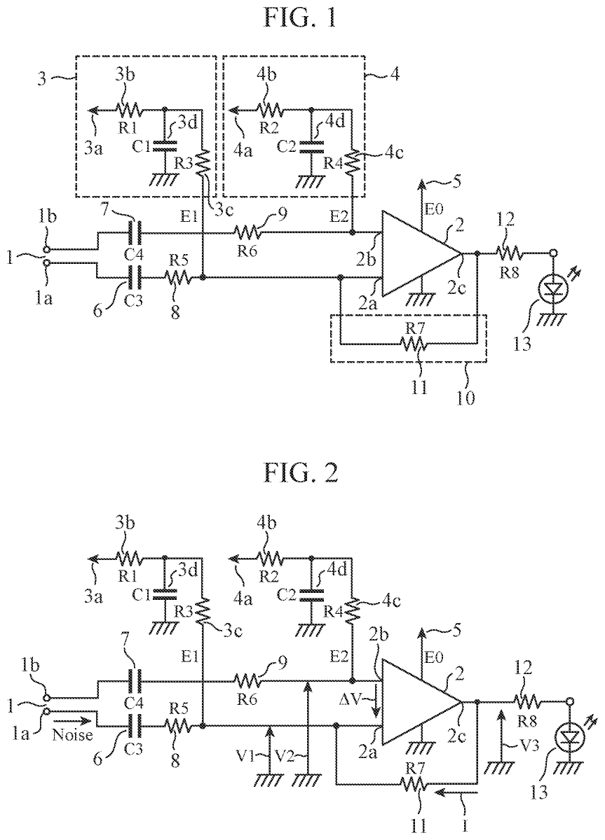

FIG. 1 is a configuration diagram illustrating a noise detection circuit according to a first embodiment.

In FIG. 1, a differential input terminal 1 includes a terminal 1a and a terminal 1b.

The noise detection circuit illustrated in FIG. 1 is a circuit that detects noise input via the terminal 1a. The waveform of the noise may be a pulse shape, for example.

A comparator 2 includes a first input terminal 2a, a second input terminal 2b, and an output terminal 2c.

The comparator 2 compares the potential V1 of the first input terminal 2a with the potential V2 of the second input terminal 2b, and outputs a result of comparison of the potentials through the output terminal 2c.

A first reference voltage applying circuit 3 includes a first voltage source 3a, a first resistor 3b, a resistor 3c, and a first capacitor 3d.

While an example in which the first reference voltage applying circuit 3 includes the first voltage source 3a is illustrated in FIG. 1, the first voltage source 3a may alternatively be provided outside of the noise detection circuit.

The first reference voltage applying circuit 3 is a circuit that applies a first reference voltage E1 to the first input terminal 2a of the comparator 2.

The first voltage source 3a is a voltage source that applies a first voltage to a first end of the first resistor 3b.

The first resistor 3b has the first end connected with the first voltage source 3a, and a second end connected with a first end of the resistor 3c, and has a resistance R1.

The resistor 3c has the first end connected with the second end of the first resistor 3b, and a second end connected with the first input terminal 2a of the comparator 2, and has a resistance R3.

The first capacitor 3d has a first end connected with the second end of the first resistor 3b, and a second end connected with the ground, and has a capacitance C1.

While an example in which the first reference voltage applying circuit 3 includes only the first capacitor 3d, which is a single capacitor, is illustrated in FIG. 1, this example is not a limitation, and the first capacitor 3d may be constituted by a plurality of capacitors. Note that the capacitors may respectively have capacitances equal to each other or capacitances different from each other.

A second reference voltage applying circuit 4 includes a second voltage source 4a, a second resistor 4b, a resistor 4c, and a second capacitor 4d.

While an example in which the second reference voltage applying circuit 4 includes the second voltage source 4a is illustrated in FIG. 1, the second voltage source 4a may alternatively be provided outside of the noise detection circuit.

The second reference voltage applying circuit 4 is a circuit that applies a second reference voltage E2 to the second input terminal 2b of the comparator 2.

The second voltage source 4a is a voltage source that applies a second voltage to a first end of the second resistor 4b.

The second resistor 4b has the first end connected with the second voltage source 4a, and a second end connected with a first end of the resistor 4c, and has a resistance R2.

The resistor 4c has the first end connected with the second end of the second resistor 4b, and a second end connected with the second input terminal 2b of the comparator 2, and has a resistance R4.

The second capacitor 4d has a first end connected with the second end of the second resistor 4b, and a second end connected with the ground, and has a capacitance C2.

While an example in which the second reference voltage applying circuit 4 includes only the second capacitor 4d, which is a single capacitor, is illustrated in FIG. 1, this example is not a limitation, and the second capacitor 4d may be constituted by a plurality of capacitors. Note that the capacitors may respectively have capacitances equal to each other or capacitances difference from each other.

A driving power supply 5 is a power supply that outputs a voltage E0 for supplying driving power to the comparator 2.

While an example in which the noise detection circuit includes the driving power supply 5 is illustrated in FIG. 1, the driving power supply 5 may be a voltage source provided outside of the noise detection circuit.

A capacitor 6 has a first end connected with the terminal 1a of the differential input terminal 1, and a second end connected with a first end of a resistor 8, and has a capacitance C3.

The capacitor 6 is provided to block a direct-current (DC) component of a signal input through the terminal 1a of the differential input terminal 1.

A capacitor 7 has a first end connected with the terminal 1b of the differential input terminal 1, and a second end connected with a first end of a resistor 9, and has a capacitance C4.

The capacitor 7 is provided to block a DC component of a signal input through the terminal 1b of the differential input terminal 1.

The resistor 8 has the first end connected with the second end of the capacitor 6, and a second end connected with the first input terminal 2a of the comparator 2, and has a resistance R5.

The resistor 9 has the first end connected with the second end of the capacitor 7, and a second end connected with the second input terminal 2b of the comparator 2, and has a resistance R6.

A feedback circuit 10 is a circuit having a first end connected with the output terminal 2c of the comparator 2, and a second end connected with the first input terminal 2a of the comparator 2, and includes a resistor 11.

The resistor 11 has a first end connected with the output terminal 2c of the comparator 2, and a second end connected with the first input terminal 2a of the comparator 2, and has a resistance R7.

A resistor 12 has a first end connected with the output terminal 2c of the comparator 2, and a second end connected with a display circuit 13, and has a resistance R8.

The resistors 3c, 4c, 8, 9, 11, and 12 are provided to set the impedance of the noise detection circuit. Note that, however, the resistors 3c, 4c, 8, 9, 11, and 12 are not essential components of the noise detection circuit. Thus, the second end of the first resistor 3b may be directly connected with the first input terminal 2a of the comparator 2. In addition, the second end of the second resistor 4b may be directly connected with the second input terminal 2b of the comparator 2.

The display circuit 13 includes a light emitting diode (LED), for example.

The display circuit 13 is a circuit that displays detection of noise by causing the LED to emit light when the potential V3 of the output terminal 2c of the comparator 2 is equal to or higher than a threshold voltage of the LED.

Next, a principle of operation of the noise detection circuit will be explained with reference to FIG. 2. FIG. 2 is an explanatory diagram illustrating a noise detecting operation of the noise detection circuit illustrated in FIG. 1.

In the first embodiment, the potential difference of the differential input of the comparator 2 is represented by ΔV, the potential of the first input terminal 2a of the comparator 2 is represented by V1, the potential of the second input terminal 2b of the comparator 2 is represented by V2, and the potential of the output terminal 2c of the comparator 2 is represented by V3.

In addition, the current flowing through the feedback circuit 10 from the output terminal 2c toward the first input terminal 2a of the comparator 2 is represented by “I”.

Herein, for convenience of explanation, the voltage E0 output from the driving power supply 5 to the comparator 2 is assumed to be 3.0 (V).

In addition, the first reference voltage E1 output from the first reference voltage applying circuit 3 to the first input terminal 2a of the comparator 2 is assumed to be 1.48 (V), and the second reference voltage E2 output from the second reference voltage applying circuit 4 to the second input terminal 2b of the comparator 2 is assumed to be 1.50 (V).

In a state in which no noise is input through the terminal 1a of the differential input terminal 1, the potential V1 of the first input terminal 2a is equal to the first reference voltage E1. Thus, in the state in which no noise is input through the terminal 1a of the differential input terminal 1, the potential V1 of the first input terminal 2a is lower than the potential V2 (=E2) of the second input terminal 2b.

The comparator 2 is set so that the potential V3 of the output terminal 2c is at an L level (0 V) when the potential V1 of the first input terminal 2a is equal to or lower than the potential V2 of the second input terminal 2b.

In addition, the comparator 2 is set so that the potential V3 increases to an H level (a voltage higher than 0 V) when the potential V1 increases and becomes higher than the potential V2.

The comparator 2 corresponds to an operational amplifier having an amplification factor of “g”, and the potential V3 of the output terminal 2c of the comparator 2 is a potential (=ΔV×g) directly proportional to the potential difference ΔV(=V1−V2) when the potential V1 is higher than the potential V2.

In the first embodiment, all voltage drops at the output of the comparator 2 will be ignored.

First, the second reference voltage applying circuit 4 sets the potential V2 of the second input terminal 2b of the comparator 2 to E2 as expressed in the following formula (1) by applying the second reference voltage E2 to the second input terminal 2b of the comparator 2.

V2=E2 (1)

Subsequently, the first reference voltage applying circuit 3 sets the potential V1 of the first input terminal 2a of the comparator 2 to E1 as expressed in the following formula (2) by applying the first reference voltage E1 to the first input terminal 2a of the comparator 2.

V1=E1 (2)

In the state in which the potential V1 of the first input terminal 2a is set to E1 and the potential V2 of the second input terminal 2b is set to E2, V1<V2 is satisfied, and thus the potential V3 of the output terminal 2c of the comparator 2 is at the L level.

The state in which the potential V3 of the output terminal 2c of the comparator 2 is at the L level is a noise input waiting state in which noise can be detected.

When noise is input through the terminal 1a of the differential input terminal 1, a potential V_{N} due to the noise is applied to the first input terminal 2a.

Thus, the potential V1 of the first input terminal 2a increases by the amount corresponding to the application of the potential V_{N} due to the noise as expressed in the following formula (3).

V1=E1+V_{N} (3)

Because the potential V_{N} due to the noise is high, the potential V1 of the first input terminal 2a may become higher than the potential V2 of the second input terminal 2b (V1>V2).

When the potential V1 of the first input terminal 2a becomes higher than the potential V2 of the second input terminal 2b (V1>V2), the potential V3 of the output terminal 2c of the comparator 2 changes from the L level to the H level to be a potential directly proportional to the potential difference ΔV (=V1−V2).

When the potential V3 of the output terminal 2c of the comparator 2 increases and becomes higher than the threshold voltage of the LED, a forward current flows through the LED of the display circuit 13, and the LED thus emits light. The light emission of the LED of the display circuit 13 enables a user to recognize detection of noise.

While an example in which the LED of the display circuit 13 emits light when the potential V3 of the output terminal 2c of the comparator 2 is higher than the threshold voltage of the LED is presented in the first embodiment, the color of the emitted light may be changed depending on the level of the forward current.

Note that, in a state in which the potential V3 of the output terminal 2c of the comparator 2 is equal to or lower than the potential V1 of the first input terminal 2a (V1≥V3), the current I does not flow from the output terminal 2c toward the first input terminal 2a of the comparator 2.

When the potential V3 of the output terminal 2c of the comparator 2 becomes higher than the potential V1 of the first input terminal 2a (V1<V3) as the potential V1 of the first input terminal 2a increases, the current I flows through the feedback circuit 10 from the output terminal 2c of the comparator 2 toward the first input terminal 2a.

Once the current I flows through the feedback circuit 10, the state in which the potential V1 of the first input terminal 2a is higher than the potential V2 of the second input terminal 2b continues.

Thus, even when the state in which the potential V_{N} due to the noise is applied to the first input terminal 2a is terminated in a short time because the noise input through the terminal 1a of the differential input terminal 1 has a narrow pulse width, the state in which the potential V1 of the first input terminal 2a is higher than the potential V2 of the second input terminal 2b continues.

As the state in which the potential V1 of the first input terminal 2a is higher than the potential V2 of the second input terminal 2b continues, the potential V3 of the output terminal 2c of the comparator 2 is maintained at the H level, and the light emission of the LED of the display circuit 13 is thus continued.

In the first embodiment, the noise detection circuit that detects noise input through the terminal 1a of the differential input terminal 1 is described.

In order for the noise detection circuit to detect noise input through the terminal 1b of the differential input terminal 1, the second end of the feedback circuit 10, whose first end is connected with the output terminal 2c of the comparator 2, needs to be connected with the second input terminal 2b of the comparator 2, as illustrated in FIG. 3.

FIG. 3 is an explanatory diagram illustrating the noise detecting operation of the noise detection circuit capable of detecting noise input through the terminal 1b of the differential input terminal 1.

For detection of noise input through the terminal 1b of the differential input terminal 1, the first reference voltage E1 applied by the first reference voltage applying circuit 3 is set to be higher than the second reference voltage E2 applied by the second reference voltage applying circuit 4.

The comparator 2 is set so that the potential V3 of the output terminal 2c is at the L level (0 V) when the potential V2 of the second input terminal 2b is equal to or lower than the potential V1 of the first input terminal 2a.

In addition, the comparator 2 is set so that the potential V3 becomes at the H level when the potential V2 increases and becomes higher than the potential V1.

The comparator 2 corresponds to the operational amplifier having an amplification factor of “g”, and the potential V3 of the output terminal 2c of the comparator 2 is a potential (=ΔV×g) directly proportional to the potential difference ΔV (=V2−V1) when the potential V2 is higher than the potential V1.

First, the first reference voltage applying circuit 3 sets potential V1 of the first input terminal 2a of the comparator 2 to E1 as expressed in the aforementioned formula (2) by applying the first reference voltage E1 to the first input terminal 2a of the comparator 2.

Subsequently, the second reference voltage applying circuit 4 sets the potential V2 of the second input terminal 2b of the comparator 2 to E2 as expressed in the aforementioned formula (1) by applying the second reference voltage E2 to the second input terminal 2b of the comparator 2.

In the state in which the potential V1 of the first input terminal 2a is set to E1 and the potential V2 of the second input terminal 2b is set to E2, V1>V2 is satisfied, and thus the potential V3 of the output terminal 2c of the comparator 2 is at the L level.

When noise is input through the terminal 1b of the differential input terminal 1, the potential V_{N} due to the noise is applied to the second input terminal 2b.

Thus, the potential V2 of the second input terminal 2b increases by the amount corresponding to the application of the potential V_{N} due to the noise as expressed in the following formula (4).

V2=E2+V_{N} (4)

Because the potential V_{N} due to the noise is high, the potential V2 of the second input terminal 2b may become higher than the potential V1 of the first input terminal 2a (V1<V2).

When the potential V2 of the second input terminal 2b becomes higher than the potential V1 of the first input terminal 2a (V1<V2), the potential V3 of the output terminal 2c of the comparator 2 changes from the L level to the H level to be a potential directly proportional to the potential difference ΔV (=V2−V1).

When the potential V3 of the output terminal 2c of the comparator 2 increases and becomes higher than the threshold voltage of the LED, a forward current flows through the LED of the display circuit 13, and the LED thus emits light. The light emission of the LED of the display circuit 13 enables a user to recognize detection of noise.

Note that, in a state in which the potential V3 of the output terminal 2c of the comparator 2 is equal to or lower than the potential V2 of the second input terminal 2b (V2≥V3), the current I does not flow from the output terminal 2c of the comparator 2 toward the second input terminal 2b.

When the potential V3 of the output terminal 2c of the comparator 2 becomes higher than the potential V2 of the second input terminal 2b (V2<V3) as the potential V2 of the second input terminal 2b increases, the current I flows through the feedback circuit 10 from the output terminal 2c of the comparator 2 toward second input terminal 2b.

Once the current I flows through the feedback circuit 10, the state in which the potential V2 of the second input terminal 2b is higher than the potential V1 of the first input terminal 2a continues.

Thus, even when the state in which the potential V_{N} due to the noise is applied to the second input terminal 2b is terminated in a short time because the noise input through the terminal 1b of the differential input terminal 1 has a narrow pulse width, the state in which the potential V2 of the second input terminal 2b is higher than the potential V1 of the first input terminal 2a continues.

As the state in which the potential V2 of the second input terminal 2b is higher than the potential V1 of the first input terminal 2a continues, the potential V3 of the output terminal 2c of the comparator 2 is maintained at the H level, and the light emission of the LED of the display circuit 13 is thus continued.

In the first embodiment described above, the noise detection circuit incudes the first reference voltage applying circuit 3 that applies the first reference voltage E1 to the first input terminal 2a of the comparator 2, the second reference voltage applying circuit 4 that applies the second reference voltage E2 to the second input terminal 2b of the comparator 2, and the feedback circuit 10 having the first end connected with the output terminal 2c of the comparator 2 and the second end connected with the first input terminal 2a or the second input terminal 2b of the comparator 2. Thus, noise can be detected with only one comparator 2.

Second Embodiment.

The first embodiment has presented an example in which, for detection of noise input through the terminal 1a of the differential input terminal 1, the second reference voltage applying circuit 4 sets the potential V2 of the second input terminal 2b to the second reference voltage E2, and the first reference voltage applying circuit 3 then sets the potential V1 of the first input terminal 2a to the first reference voltage E1.

The reason for which the potential V2 of the second input terminal 2b is first set to the second reference voltage E2 and the potential V1 of the first input terminal 2a is then set to the first reference voltage E1 is as follows.

If the potential V1 of the first input terminal 2a is set to the first reference voltage E1 before the potential V2 of the second input terminal 2b is set to the second reference voltage E2, the potential V3 of the output terminal 2c of the comparator 2 is fixed to the H level, and noise cannot be detected.

In a second embodiment, even when the timing at which a first voltage is output from the first voltage source 3a and the timing at which a second voltage is output from the second voltage source 4a are substantially the same as each other, the second reference voltage applying circuit 4 first sets the potential V2 of the second input terminal 2b to the second reference voltage E2, and the first reference voltage applying circuit 3 then sets the potential V1 of the first input terminal 2a to the first reference voltage E1.

Specifically, the second embodiment is as follows.

For detection of noise input through the terminal 1a of the differential input terminal 1, the first reference voltage E1 is assumed to be set to a voltage lower than the second reference voltage E2 in the noise detection circuit illustrated in FIG. 1, in a manner similar to the first embodiment.

In the second embodiment, a time constant determined by the product of the resistance R1 of the first resistor 3b and the capacitance C1 of the first capacitor 3d is assumed to be a first time constant τ1. In addition, a time constant determined by the product of the resistance R2 of the second resistor 4b and the capacitance C2 of the second capacitor 4d is assumed to be a second time constant τ2.

In this case, the resistance R1 of the first resistor 3b, the capacitance C1 of the first capacitor 3d, the resistance R2 of the second resistor 4b, and the capacitance C2 of the second capacitor 4d are set so that the first time constant τ1 is larger than the second time constant τ2.

When the first time constant τ1 is larger than the second time constant τ2, even if the timing at which the first voltage is output from the first voltage source 3a and the timing at which the second voltage is output from the second voltage source 4a are the same as each other, the timing at which the first reference voltage E1 is output from the first reference voltage applying circuit 3 is later than the timing at which the second reference voltage E2 is output from the second reference voltage applying circuit 4.

As a result, after the second reference voltage applying circuit 4 sets the potential V2 of the second input terminal 2b to the second reference voltage E2, the first reference voltage applying circuit 3 then sets the potential V1 of the first input terminal 2a to the first reference voltage E1.

For detection of noise input through the terminal 1b of the differential input terminal 1, the first reference voltage E1 is assumed to be set to a voltage higher than the second reference voltage E2 in the noise detection circuit illustrated in FIG. 3, in a manner similar to the first embodiment.

In this case, the resistance R1 of the first resistor 3b, the capacitance C1 of the first capacitor 3d, the resistance R2 of the second resistor 4b, and the capacitance C2 of the second capacitor 4d are set so that the first time constant τ1 is smaller than the second time constant τ2.

When the first time constant τ1 is smaller than the second time constant τ2, even if the timing at which the first voltage is output from the first voltage source 3a and the timing at which the second voltage is output from the second voltage source 4a are the same as each other, the timing at which the second reference voltage E2 is output from the second reference voltage applying circuit 4 is later than the timing at which the first reference voltage E1 is output from the first reference voltage applying circuit 3.

As a result, after the first reference voltage applying circuit 3 sets the potential V1 of the first input terminal 2a to the first reference voltage E1, the second reference voltage applying circuit 4 then sets the potential V2 of the second input terminal 2b to the second reference voltage E2.

In the second embodiment described above, for detection of noise input through the terminal 1a of the differential input terminal 1, the first reference voltage E1 is set to be lower than the second reference voltage E2 and the first time constant τ1 is set to be larger than the second time constant τ2. In addition, for detection of noise input through the terminal 1b of the differential input terminal 1, the first reference voltage E1 is set to be higher than the second reference voltage E2 and the first time constant τ1 is set to be smaller than the second time constant τ2. Thus, even if the timing at which the first voltage is output from the first voltage source 3a and the timing at which the second voltage is output from the second voltage source 4a are the same as each other, the lower reference voltage E of the first and second reference voltages E1 and E2 can be first set. As a result, it is possible to prevent the occurrence of a situation in which the potential V3 of the output terminal 2c of the comparator 2 is fixed to the H level and noise cannot be detected.

Third Embodiment.

The noise detection circuit of the first embodiment is an example in which, when the current I flows through the feedback circuit 10, the potential V3 of the output terminal 2c of the comparator 2 is maintained at the H level.

In a third embodiment, a noise detection circuit capable of returning the potential V3 of the output terminal 2c of the comparator 2 from the H level to the L level will be described.

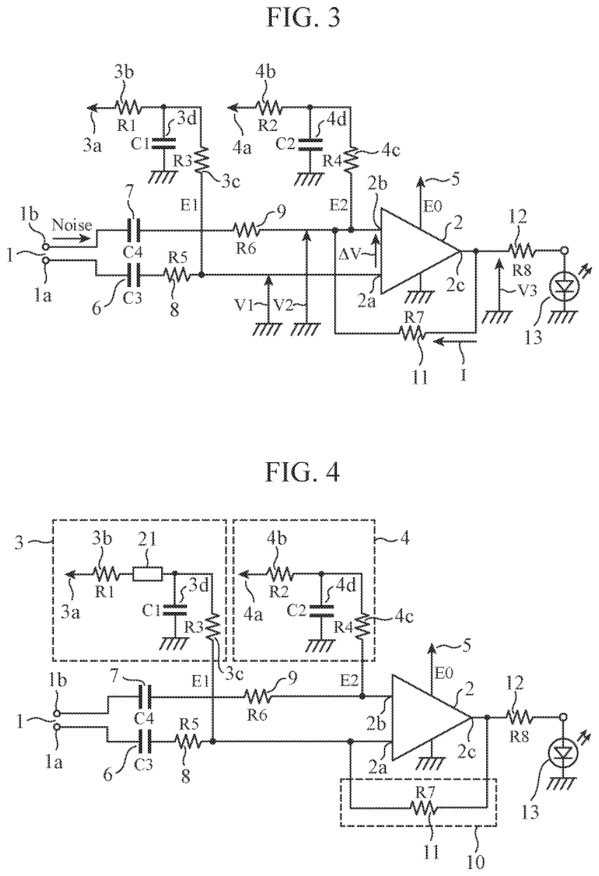

FIG. 4 is a configuration diagram illustrating the noise detection circuit according to the third embodiment. In FIG. 4, reference numerals that are the same as those in FIG. 1 represent the same or corresponding components, and description thereof will be omitted.

The first reference voltage applying circuit 3 includes a reset circuit 21. The reset circuit 21 has a first end connected with the second end of the first resistor 3b, and a second end connected with the first input terminal 2a via the resistor 3c.

The reset circuit 21 is a circuit that switches between electrical connection and disconnection between the first resistor 3b and the first input terminal 2a.

In the third embodiment, an example in which a DIP switch or a tact switch is used as the reset circuit 21 is assumed, for example, but the reset circuit 21 is not limited to a DIP switch or a tact switch and may be a proximity sensor such as a reed switch or a magnetoresistive element, for example. In addition, the reset circuit 21 may be a circuit that switches between connection and disconnection by a direct operation or may be a circuit that switches between connection and disconnection by a remote operation.

In the third embodiment as well, in a manner similar to the first embodiment, the potential V3 of the output terminal 2c of the comparator 2 may increase and become higher than threshold voltage of the LED. When the potential V3 of the output terminal 2c of the comparator 2 is higher than the threshold voltage of the LED, a forward current flows and the LED of the display circuit 13 thus emits light in a manner similar to the first embodiment. The light emission of the LED of the display circuit 13 enables a user to recognize detection of noise.

In the first embodiment, when the current I once flows through the feedback circuit 10, the state in which the potential V1 of the first input terminal 2a is higher than the potential V2 of the second input terminal 2b continues, and the potential V3 of the output terminal 2c of the comparator 2 is thus maintained at the H level.

When noise input through the terminal 1a of the differential input terminal 1 has a narrow pulse width, the state in which the potential V_{N} due to the noise is applied to the first input terminal 2a is terminated in a short time. Even when the state in which the potential V_{N} due to the noise is applied to the first input terminal 2a is terminated in a short time, the potential V3 of the output terminal 2c of the comparator 2 is maintained at the H level, and the emission of the LED of the display circuit 13 is thus continued. Thus, it is possible to prevent the occurrence of a situation in which the user overlooks the detection of noise.

The noise detection circuit illustrated in FIG. 1 according to the first embodiment, however, does not include means for returning the potential V3 of the output terminal 2c of the comparator 2 from the H level to the L level. Thus, noise input subsequently cannot be detected unless the entire noise detection circuit is reset in such a manner that power supply to the noise detection circuit is turned off once, for example.

In the third embodiment, because the first reference voltage applying circuit 3 includes the reset circuit 21, the potential V3 of the output terminal 2c of the comparator 2 can be returned from the H level to the L level without resetting of the entire noise detection circuit.

For detection of noise input through the terminal 1a of the differential input terminal 1, the reset circuit 21 electrically connects the first resistor 3b with the first input terminal 2a by connecting the first resistor 3b with the resistor 3c.

When noise input through the terminal 1a of the differential input terminal 1 is detected and the potential V3 of the output terminal 2c of the comparator 2 is then returned from the H level to the L level, the reset circuit 21 disconnects the first resistor 3b and the first input terminal 2a from each other by disconnecting the first resistor 3b and the resistor 3c from each other.

As a result of disconnection between the first resistor 3b and the first input terminal 2a, when no noise is input through the terminal 1a of the differential input terminal 1, the potential V1 of the first input terminal 2a becomes lower than the potential V2 of the second input terminal 2b, and the potential V3 of the output terminal 2c of the comparator 2 is thus returned to the L level.

While FIG. 4 shows one example of the noise detection circuit that detects noise input through the terminal 1a of the differential input terminal 1, the second reference voltage applying circuit 4 includes a reset circuit 22 in a case of a noise detection circuit that detects noise input through the terminal 1b of the differential input terminal 1 as illustrated in FIG. 5.

FIG. 5 is a configuration diagram illustrating another noise detection circuit according to the third embodiment. In FIG. 5, reference numerals that are the same as those in FIG. 3 represent the same or corresponding components, and description thereof will be omitted.

The second reference voltage applying circuit 4 includes the reset circuit 22. The reset circuit 22 has a first end connected with the second end of the second resistor 4b, and a second end connected with the second input terminal 2b via the resistor 4c.

The reset circuit 22 is a circuit that switches between electrical connection and disconnection between the second resistor 4b and the second input terminal 2b.

In the third embodiment, an example in which a DIP switch or a tact switch is used as the reset circuit 22 is assumed, for example, but the reset circuit 22 is not limited to a DIP switch or a tact switch and may be a proximity sensor such as a reed switch or a magnetoresistive element, for example. In addition, the reset circuit 22 may be a circuit that switches between connection and disconnection by a direct operation or may be a circuit that switches between connection and disconnection by a remote operation.

For detection of noise input through the terminal 1b of the differential input terminal 1 as well, when the current I once flows through the feedback circuit 10, a state in which the potential V2 of the second input terminal 2b is higher than the potential V1 of the first input terminal 2a continues, and the potential V3 of the output terminal 2c of the comparator 2 is thus maintained at the H level.

When noise input through the terminal 1b of the differential input terminal 1 has a narrow pulse width, the state in which the potential V_{N} due to the noise is applied to the second input terminal 2b is terminated in a short time. Even when the state in which the potential V_{N} due to the noise is applied to the second input terminal 2b is terminated in a short time, the potential V3 of the output terminal 2c of the comparator 2 is maintained at the H level, and the emission of the LED of the display circuit 13 is thus continued. Thus, it is possible to prevent the occurrence of a situation in which the user overlooks the detection of noise.

The noise detection circuit illustrated in FIG. 3 according to the first embodiment, which detects noise input through the terminal 1b of the differential input terminal 1, does not include means for returning the potential V3 of the output terminal 2c of the comparator 2 from the H level to the L level. Thus, noise input subsequently cannot be detected unless the entire noise detection circuit is reset in such a manner that power supply to the noise detection circuit is turned off once, for example.

In the third embodiment, because the second reference voltage applying circuit 4 includes the reset circuit 22, the potential V3 of the output terminal 2c of the comparator 2 can be returned from the H level to the L level without resetting of the entire noise detection circuit.

For detection of noise input through the terminal 1b of the differential input terminal 1, the reset circuit 22 electrically connects the second resistor 4b with the second input terminal 2b by connecting the second resistor 4b with the resistor 4c.

When noise input through the terminal 1b of the differential input terminal 1 is detected and the potential V3 of the output terminal 2c of the comparator 2 is then returned from the H level to the L level, the reset circuit 22 disconnects the second resistor 4b and the second input terminal 2b from each other by disconnecting the second resistor 4b and the resistor 4c from each other.

As a result of disconnection between the second resistor 4b and the second input terminal 2b, when no noise is input through the terminal 1b of the differential input terminal 1, the potential V2 of the second input terminal 2b becomes lower than the potential V1 of the first input terminal 2a, and the potential V3 of the output terminal 2c of the comparator 2 is thus returned to the L level.

Fourth Embodiment.

In the first embodiment, an example in which the feedback circuit 10 includes the resistor 11 is presented.

In a fourth example, an example in which the feedback circuit 10 includes a diode 23 in addition to the resistor 11 will be described.

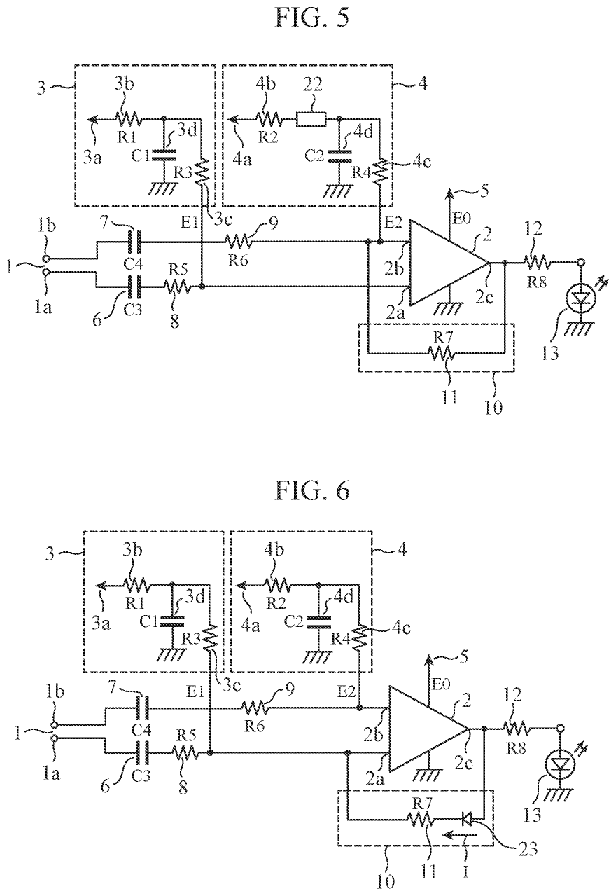

FIG. 6 is a configuration diagram illustrating a noise detection circuit according to the fourth embodiment. In FIG. 6, reference numerals that are the same as those in FIG. 1 represent the same or corresponding components, and description thereof will be omitted.

The feedback circuit 10 includes the resistor 11 and the diode 23.

The diode 23 has an anode connected with the output terminal 2c of the comparator 2, and a cathode electrically connected with the first input terminal 2a of the comparator 2 via the resistor 11.

The diode 23 is an element that causes the current I, which is a forward current, to flow from the output terminal 2c toward the first input terminal 2a when the potential V3 of the output terminal 2c of the comparator 2 is higher than the potential V1 of the first input terminal 2a of the comparator 2 and the potential difference (V3−V1) between the potential V3 of the output terminal 2c and the potential V1 of the first input terminal 2a is higher than the forward voltage of the diode 23.

In the fourth embodiment, for simplicity of explanation, voltage drops at the resistor 11 will be ignored.

While an example in which the diode 23 is applied to the noise detection circuit illustrated in FIG. 1 is presented in FIG. 6, the diode 23 may be applied to the noise detection circuit illustrated in FIG. 4.

For example, in the noise detection circuit illustrated in FIG. 1, when the potential V1 of the first input terminal 2a of the comparator 2 is higher than the potential V3 of the output terminal 2c of the comparator 2, the direction of the current I flowing through the feedback circuit 10 is a direction from the first input terminal 2a toward the output terminal 2c.

Thus, the current I flowing through the feedback circuit 10 flows as an excess current to the display circuit 13. As a result, even when a weak signal that need not be detected as noise is input, for example, the LED may emit light.

In the fourth embodiment, the feedback circuit 10 includes the diode 23, which prevents the current I from flowing from the first input terminal 2a toward the output terminal 2c.

Thus, even when the potential V1 of the first input terminal 2a of the comparator 2 is higher than the potential V3 of the output terminal 2c of the comparator 2, the current I from the first input terminal 2a toward the output terminal 2c does not flow as an excess current to the display circuit 13.

In a manner similar to the first embodiment, the potential V3 of the output terminal 2c of the comparator 2 increases when noise is input through the terminal 1a of the differential input terminal 1.

The diode 23 causes the current I, which is a forward current, to flow when the potential V3 of the output terminal 2c increases and becomes higher than the potential V1 of the first input terminal 2a and the potential difference (V3−V1) between the potential V3 of the output terminal 2c and the potential V1 of the first input terminal 2a becomes higher than the forward voltage of the diode 23.

In a manner similar to the first embodiment, when the current I, which is a forward current flows through the diode 23, the state in which the potential V1 of the first input terminal 2a is higher than the potential V2 of the second input terminal 2b continues. As a result, the potential V3 of the output terminal 2c of the comparator 2 is maintained at the H level.

In the fourth embodiment described above, the feedback circuit 10 includes the diode 23 having the anode connected with the output terminal 2c of the comparator 2 and the cathode electrically connected with the first input terminal 2a. The diode 23 is configured to cause a forward current to flow from the output terminal 2c toward the first input terminal 2a when the potential V3 of the output terminal 2c is higher than the potential V1 of the first input terminal 2a and the potential difference (V3−V1) between the potential V3 of the output terminal 2c and the potential V1 of the first input terminal 2a is higher than the forward voltage of the diode 23. Thus, when the potential V1 of the first input terminal 2a of the comparator 2 is higher than the potential V3 of the output terminal 2c of the comparator 2, the current I from the first input terminal 2a toward the output terminal 2c is prevented from flowing as an excess current to the display circuit 13.

While the noise detection circuit capable of detecting noise input through the terminal 1a of the differential input terminal 1 is illustrated in FIG. 6, the diode 23 may be applied to the noise detection circuit illustrated in FIG. 3 or FIG. 5 for a noise detection circuit capable of detecting noise input through the terminal 1b of the differential input terminal 1.

FIG. 7 is a configuration diagram illustrating another noise detection circuit according to the fourth embodiment, in which the diode 23 is applied to the noise detection circuit, and the noise detection circuit is capable of detecting noise input through the terminal 1b of the differential input terminal 1.

Fifth Embodiment.

The first embodiment presents an example in which the first voltage output from the first voltage source 3a is applied to the first end of the first resistor 3b of the first reference voltage applying circuit 3, and the second voltage output from the second voltage source 4a is applied to the first end of the second resistor 4b of the second reference voltage applying circuit 4.

In a fifth embodiment, an example in which a first reference voltage applying circuit 31 includes a first voltage dividing circuit 32 that divides the voltage E0 output from the driving power supply 5, and a voltage obtained by the division by the first voltage dividing circuit 32 is applied as the first voltage to the first end of the first resistor 3b will be described.

In addition, an example in which the second reference voltage applying circuit 4 includes a second voltage dividing circuit 42 that divides the voltage E0 output from the driving power supply 5, and a voltage obtained by the division by the second voltage dividing circuit 42 is applied as the first voltage to the first end of the second resistor 4b will be described.

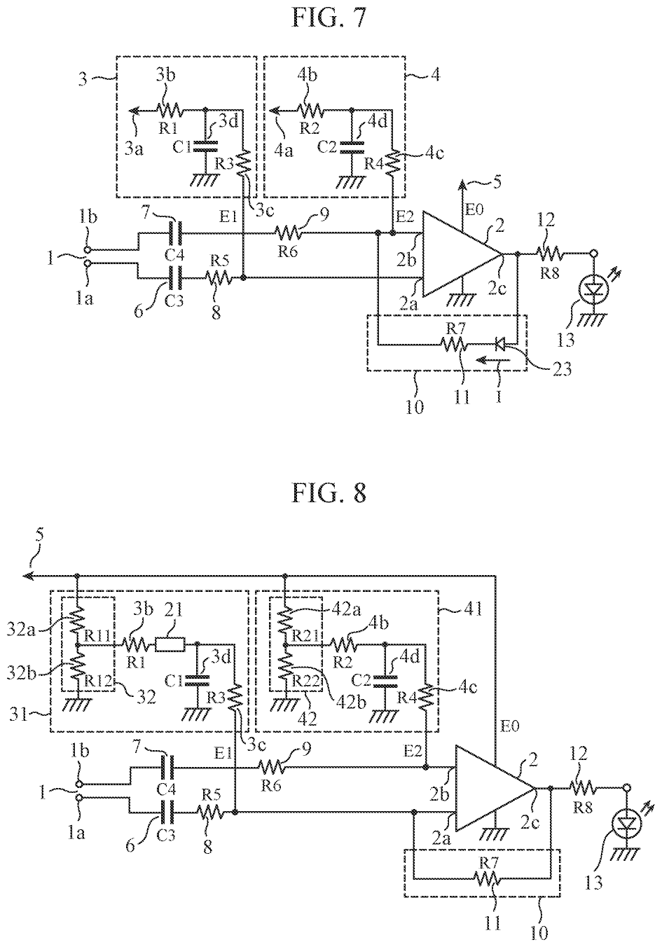

FIG. 8 is a configuration diagram illustrating a noise detection circuit according to the fifth embodiment. In FIG. 8, reference numerals that are the same as those in FIGS. 1 and 4 represent the same or corresponding components, and description thereof will be omitted.

The first reference voltage applying circuit 31 includes the first resistor 3b, the resistor 3c, the first capacitor 3d, and the first voltage dividing circuit 32. The first reference voltage applying circuit 31 is a circuit that applies the first reference voltage E1 to the first input terminal 2a of the comparator 2.

The first voltage dividing circuit 32 includes voltage dividing resistors 32a and 32b.

The first voltage dividing circuit 32 is a circuit that divides the voltage E0 output from the driving power supply 5, and outputs a voltage obtained by the division as the first voltage to the first end of the first resistor 3b.

The voltage dividing resistor 32a has a first end connected with the driving power supply 5, and a second end connected with each of the first end of the first resistor 3b and the first end of the voltage dividing resistor 32b, and has a resistance R11.

The voltage dividing resistor 32b has a first end connected with each of the first end of the first resistor 3b and the second end of the voltage dividing resistor 32a, and a second end connected with the ground, and has a resistance R12.

The second reference voltage applying circuit 41 includes the second resistor 4b, the resistor 4c, the second capacitor 4d, and the second voltage dividing circuit 42. The second reference voltage applying circuit 41 is a circuit that applies the second reference voltage E2 to the second input terminal 2b of the comparator 2.

The second voltage dividing circuit 42 includes voltage dividing resistors 42a and 42b.

The second voltage dividing circuit 42 is a circuit that divides the voltage E0 output from the driving power supply 5, and outputs a voltage obtained by the division as the second voltage to the first end of the second resistor 4b.

The voltage dividing resistor 42a has a first end connected with the driving power supply 5, and a second end connected with each of the first end of the second resistor 4b and the first end of the voltage dividing resistor 42b, and has a resistance R21.

The voltage dividing resistor 42b has a first end connected with each of the first end of the second resistor 4b and the second end of the voltage dividing resistor 42a, and a second end connected with the ground, and has a resistance R22.

While the first reference voltage applying circuit 31 includes the reset circuit 21 in the noise detection circuit illustrated in FIG. 8, the first reference voltage applying circuit 31 may not include the reset circuit 21 in the noise detection circuit.

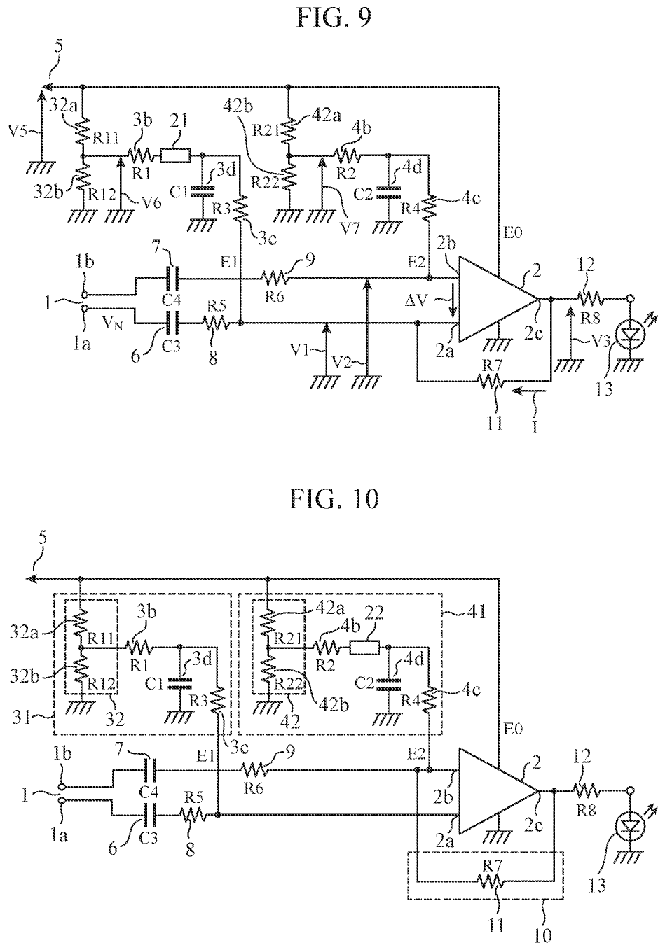

Next, a principle of operation of the noise detection circuit will be explained with reference to FIG. 9. FIG. 9 is an explanatory diagram illustrating a noise detecting operation of the noise detection circuit illustrated in FIG. 8.

In the fifth embodiment, noise input through the terminal 1a of the differential input terminal 1 is assumed to be detected.

In the fifth embodiment, the potential difference of the differential input of the comparator 2 is represented by ΔV, the potential of the first input terminal 2a of the comparator 2 is represented by V1, the potential of the second input terminal 2b of the comparator 2 is represented by V2, and the potential of the output terminal 2c of the comparator 2 is represented by V3.

In addition, the current flowing from the output terminal 2c of the comparator 2 to the first input terminal 2a is represented by “I”.

Herein, for convenience of explanation, the voltage E0 output from the driving power supply 5 to the comparator 2 is assumed to be 3.0 (V).

In addition, the potential of an output of the driving power supply 5 is represented by V5 (=E0), the potential between the voltage dividing resistor 32a and the voltage dividing resistor 32b is represented by V6, and the potential between the voltage dividing resistor 42a and the voltage dividing resistor 42b is represented by V7.

In addition, the resistance R11 of the voltage dividing resistor 32a is assumed to be 5 (kΩ), the resistance R12 of the voltage dividing resistor 32b is assumed to be 4 (kΩ), the resistance R21 of the voltage dividing resistor 42a is assumed to be 5 (kΩ), and the resistance R22 of the voltage dividing resistor 42b is assumed to be 5 (kΩ).

When the resistance R11 is 5 (kΩ), the resistance R12 is 4 (kΩ), the resistance R21 is 5 (kΩ), and the resistance R22 is 5 (kΩ), the potential V6 between the voltage dividing resistor 32a and the voltage dividing resistor 32b is as expressed in the following formula (5), and the potential V7 between the voltage dividing resistor 42a and the voltage dividing resistor 42b is as expressed in the following formula (6).

$$\begin{matrix}\begin{matrix}V 6 = V 5 \times \frac{{R}_{12}}{{R}_{11} + {R}_{12}} \\ = 3.0 \times \frac{4}{5 + 4} \\ 1.33 ( V )\end{matrix} & ( 5 ) \\ \begin{matrix}V 7 = V 5 \times \frac{{R}_{22}}{{R}_{21} + {R}_{22}} \\ = 3.0 \times \frac{5}{5 + 5} \\ 1.50 ( V )\end{matrix} & ( 6 )\end{matrix}$$

The resistance R1 of the first resistor 3b, the resistance R3 of the resistor 3c, the resistance R2 of the second resistor 4b, and the resistance R4 of the resistor 4c are set in view of the potential V6 and the potential V7 so that the potential V1 of the first input terminal 2a becomes a potential lower than the potential V2 of the second input terminal 2b in a state in which no noise is input through the terminal 1a of the differential input terminal 1.

A noise detection circuit that operates in a manner similar to those in the first embodiment, etc. is achieved by setting the potential V1 of the first input terminal 2a to be a potential lower than the potential V2 of the second input terminal 2b in the state in which no noise is input through the terminal 1a of the differential input terminal 1.

In the fifth embodiment, the first voltage source 3a and the second voltage source 4a are not needed, and only the driving power supply 5 may be provided as a single power supply inside or outside the noise detection circuit.

While the noise detection circuit capable of detecting noise input through the terminal 1a of the differential input terminal 1 is illustrated in FIG. 8, the first reference voltage applying circuit 31 and the second reference voltage applying circuit 41 may be applied to the noise detection circuit illustrated in FIG. 3 or FIG. 5, for example, for a noise detection circuit capable of detecting noise input through the terminal 1b of the differential input terminal 1. The reset circuit 21 included in the first reference voltage applying circuit 31 is, however, not needed.

FIG. 10 is a configuration diagram illustrating another noise detection circuit according to the fifth embodiment, in which the first reference voltage applying circuit 31 and the second reference voltage applying circuit 41 are applied to the noise detection circuit illustrated in FIG. 10, and the noise detection circuit is capable of detecting noise input through the terminal 1b of the differential input terminal 1.

The fifth embodiment presents a configuration example in which the first voltage dividing circuit 32 includes the voltage dividing resistors 32a and 32b, and the second voltage dividing circuit 42 includes the voltage dividing resistors 42a and 42b.

Each of the first voltage dividing circuit 32 and the second voltage dividing circuit 42 can divide the voltage E0 output from the driving power supply 5, but this example is not a limitation.

For example, variable resistors may be used instead of the voltage dividing resistors 32a, 32b, 42a, and 42b, so that each of the first reference voltage E1 output from the first reference voltage applying circuit 31 and the second reference voltage E2 output from the second reference voltage applying circuit 41 can be adjusted.

Sixth Embodiment.

In the fifth embodiment, an example in which the feedback circuit 10 includes the resistor 11 is presented.

In a sixth embodiment, an example in which the feedback circuit 10 includes the diode 23 in addition to the resistor 11 will be described.

FIG. 11 is a configuration diagram illustrating a noise detection circuit according to the sixth embodiment. In FIG. 11, reference numerals that are the same as those in FIGS. 1 and 8 represent the same or corresponding components, and description thereof will be omitted.

The feedback circuit 10 includes the resistor 11 and the diode 23.

For example, in the noise detection circuit illustrated in FIG. 8, when the potential V1 of the first input terminal 2a of the comparator 2 is higher than the potential V3 of the output terminal 2c of the comparator 2, the direction of the current I flowing through the feedback circuit 10 is a direction from the first input terminal 2a toward the output terminal 2c.

Thus, the current I flowing through the feedback circuit 10 flows as an excess current to the display circuit 13. As a result, even when a weak signal that need not be detected as noise is input, for example, the LED may emit light.

In the sixth embodiment, the feedback circuit 10 includes the diode 23, which prevents the current I from flowing from the first input terminal 2a toward the output terminal 2c.

Thus, even when the potential V1 of the first input terminal 2a of the comparator 2 is higher than the potential V3 of the output terminal 2c of the comparator 2, the current I from the first input terminal 2a toward the output terminal 2c does not flow as an excess current to the display circuit 13.

In a manner similar to the fifth embodiment, the potential V3 of the output terminal 2c of the comparator 2 increases when noise is input through the terminal 1a of the differential input terminal 1.

The diode 23 causes the current I, which is a forward current, to flow when the potential V3 of the output terminal 2c increases and becomes higher than the potential V1 of the first input terminal 2a and the potential difference (V3−V1) between the potential V3 of the output terminal 2c and the potential V1 of the first input terminal 2a becomes higher than the forward voltage of the diode 23.

In a manner similar to the fifth embodiment, when the current I, which is a forward current flows through the diode 23, the state in which the potential V1 of the first input terminal 2a is higher than the potential V2 of the second input terminal 2b continues. As a result, the potential V3 of the output terminal 2c of the comparator 2 is maintained at the H level.

In the sixth embodiment described above, the feedback circuit 10 includes the diode 23 having the anode connected with the output terminal 2c of the comparator 2 and the cathode electrically connected with the first input terminal 2a. The diode 23 is configured to cause a forward current to flow from the output terminal 2c toward the first input terminal 2a when the potential V3 of the output terminal 2c is higher than the potential V1 of the first input terminal 2a and the potential difference (V3−V1) between the potential V3 of the output terminal 2c and the potential V1 of the first input terminal 2a is higher than the forward voltage of the diode 23. Thus, when the potential V1 of the first input terminal 2a of the comparator 2 is higher than the potential V3 of the output terminal 2c of the comparator 2, the current I from the first input terminal 2a toward the output terminal 2c is prevented from flowing as an excess current to the display circuit 13.

While the noise detection circuit capable of detecting noise input through the terminal 1a of the differential input terminal 1 is illustrated in FIG. 11, the diode 23 may be applied to the noise detection circuit illustrated in FIG. 10 for a noise detection circuit capable of detecting noise input through the terminal 1b of the differential input terminal 1.

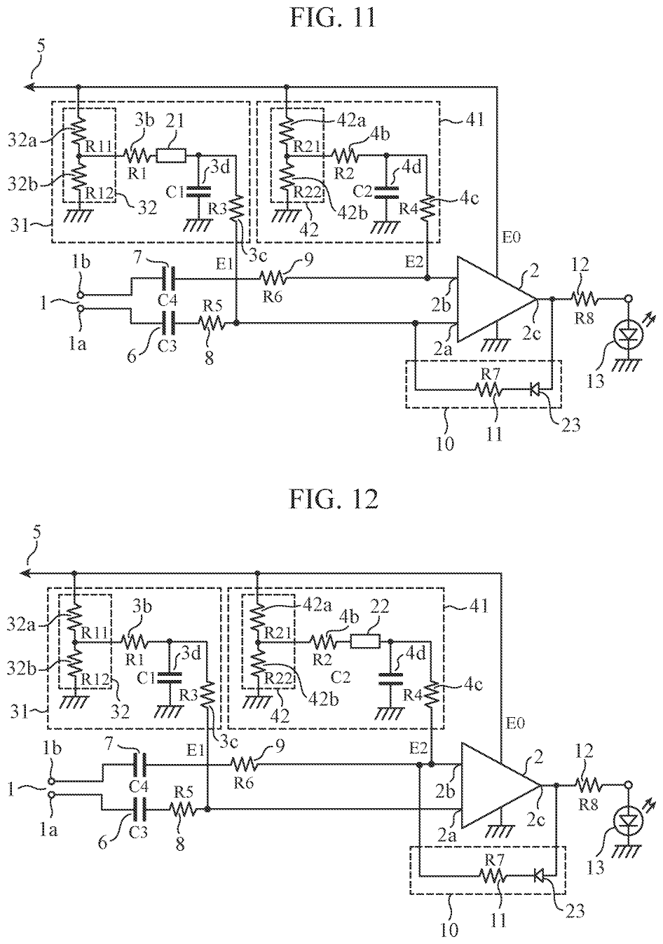

FIG. 12 is a configuration diagram illustrating another noise detection circuit according to the sixth embodiment, in which the diode 23 is applied to the noise detection circuit, and the noise detection circuit is capable of detecting noise input through the terminal 1b of the differential input terminal 1.

Note that the embodiments of the present invention can be freely combined, any components in the embodiments can be modified, and any components in the embodiments can be omitted within the scope of the invention.

### INDUSTRIAL APPLICABILITY

The present invention is suitable for a noise detection circuit including a comparator.

### REFERENCE SIGNS LIST

1: Differential input terminal,
1a and 1b: Terminal,
2: Comparator,
2a: First input terminal,
2b: Second input terminal,
2c: Output terminal,
3: First reference voltage applying circuit,
3a: First voltage source,
3b: First resistor,
3c: Resistor,
3d: First capacitor,
4: Second reference voltage applying circuit,
4a: Second voltage source,
4b: Second resistor,
4c: Resistor,
4d: Second capacitor,
5: Driving power supply,
6 and 7: Capacitor,
8 and 9: Resistor,
10: Feedback circuit,
11 and 12: Resistor,
13: Display circuit,
21 and 22: Reset circuit,
23: Diode,
31: First reference voltage applying circuit,
32: First voltage dividing circuit,
32a and 32b: Voltage dividing resistor,
41: Second reference voltage applying circuit,
42: Second voltage dividing circuit,
42a and 42b: Voltage dividing resistor.

1. A noise detection circuit comprising:
a comparator including a first input terminal, a second input terminal, and an output terminal, to compare a potential of the first input terminal with a potential of the second input terminal, and to output a result of comparison of the potentials through the output terminal;
a first reference voltage applying circuit to apply a first reference voltage to the first input terminal;
a second reference voltage applying circuit to apply a second reference voltage to the second input terminal; and
a feedback circuit having a first end connected with the output terminal and a second end connected with the first input terminal or the second input terminal, wherein
the first reference voltage applying circuit includes
a first resistor having a first end to which a first voltage is applied, and a second end connected with the first input terminal, and
a first capacitor having a first end connected with the second end of the first resistor, and a second end connected with a ground, and
the second reference voltage applying circuit includes
a second resistor having a first end to which a second voltage is applied, and a second end connected with the second input terminal, and
a second capacitor having a first end connected with the second end of the second resistor, and a second end connected with the ground.

2. The noise detection circuit according to claim 1, further comprising a display circuit to display detection of noise when a potential of the output terminal of the comparator is equal to or higher than a threshold voltage.

3. (canceled)

4. The noise detection circuit according to claim 1, wherein
the second end of the feedback circuit is connected with the first input terminal, and
when a time constant determined by a product of a resistance of the first resistor and a capacitance of the first capacitor is a first time constant, and a time constant determined by a product of a resistance of the second resistor and a capacitance of the second capacitor is a second time constant, the first reference voltage is set to be lower than the second reference voltage, and the first time constant is set to be larger than the second time constant.

5. The noise detection circuit according to claim 1, wherein
the second end of the feedback circuit is connected with the second input terminal, and
when a time constant determined by a product of a resistance of the first resistor and a capacitance of the first capacitor is a first time constant, and a time constant determined by a product of a resistance of the second resistor and a capacitance of the second capacitor is a second time constant, the first reference voltage is set to be higher than the second reference voltage, and the first time constant is set to be smaller than the second time constant.

6. The noise detection circuit according to claim 1, wherein
the first reference voltage applying circuit includes
a reset circuit having a first end connected with the second end of the first resistor, and a second end connected with the first input terminal, and
the reset circuit is a circuit to switch between electrical connection and disconnection between the first resistor and the first input terminal.

7. The noise detection circuit according to claim 1, wherein
the second reference voltage applying circuit includes
a reset circuit having a first end connected with the second end of the second resistor, and a second end connected with the second input terminal, and
the reset circuit is a circuit to switch between electrical connection and disconnection between the second resistor and the second input terminal.

8. (canceled)

9. The noise detection circuit according to claim 1, wherein
the first reference voltage applying circuit includes a first voltage dividing circuit to divide a driving voltage for supplying driving power to the comparator, and to apply a voltage obtained by the division as the first voltage to the first end of the first resistor, and
the second reference voltage applying circuit includes a second voltage dividing circuit to divide the driving voltage, and to apply a voltage obtained by the division as the second voltage to the first end of the second resistor.

10. The noise detection circuit according to claim 9, wherein the feedback circuit includes a diode having an anode electrically connected with the output terminal of the comparator, and a cathode electrically connected with the first input terminal or the second input terminal.
